(19) United States
(12) Patent Application Publication
(10) Pub. No.: US 2025/0146132 A1
(43) Pub. Date: May 8, 2025

(54) ACTIVE TEMPERATURE CONTROL OF SHOWERHEADS FOR HIGH TEMPERATURE PROCESSES

(71) Applicant: LAM RESEARCH CORPORATION, Fremont, CA (US)

(72) Inventors: Lipyeow YAP, San Jose, CA (US); Nivin VIKRAMAN, Bangalore (IN); Ramkishan Rao LINGAMPALLI, Danville, CA (US); Panya WONGSENAKHUM, Fremont, CA (US)

(21) Appl. No.: 18/727,830

(22) PCT Filed: Dec. 13, 2022
(86) PCT No.: PCT/US2022/052689

§ 371 Date: Jul. 10, 2024

Related U.S. Application Data
(60) Provisional application No. 63/302,279, filed on Jan. 24, 2022.

(51) Int. Cl. C23C 16/455

(52) U.S. Cl. CPC C23C 16/45565

(57) ABSTRACT

A showerhead for a substrate processing system includes a backplate made of a metallic material and a faceplate made of a ceramic material. The showerhead further comprises a first cooling plate arranged between the backplate and a center region of the faceplate and a plurality of heaters arranged between the backplate and a peripheral region of the faceplate.

### CROSS-REFERENCE TO RELATED APPLICATIONS

This application claims the benefit of U.S. Provisional Application No. 63/302,279, filed on Jan. 24, 2022. The entire disclosure of the above application is incorporated herein by reference.

### FIELD

The present disclosure relates generally to semiconductor processing systems and more particularly to corrosion resistant heaters for active temperature control of showerheads for high temperature processes.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Atomic Layer Deposition (ALD) is a thin-film deposition method that sequentially performs a gaseous chemical process to deposit a thin film on a surface of a material (e.g., a surface of a substrate such as a semiconductor wafer). Most ALD reactions use at least two chemicals called precursors (reactants) that react with the surface of the material one precursor at a time in a sequential, self-limiting manner. Through repeated exposure to separate precursors, a thin film is gradually deposited on the surface of the material.

Thermal ALD (T-ALD) is carried out in a heated processing chamber. The processing chamber is maintained at a sub-atmospheric pressure using a vacuum pump and a controlled flow of an inert gas. The substrate to be coated with an ALD film is placed in the processing chamber and is allowed to equilibrate with the temperature of the processing chamber before starting the ALD process.

### SUMMARY

A showerhead for a substrate processing system comprises a backplate made of a metallic material and a faceplate made of a ceramic material. The showerhead further comprises a first cooling plate arranged between the backplate and a center region of the faceplate and a plurality of heaters arranged between the backplate and a peripheral region of the faceplate.

In an additional feature, the first cooling plate and the plurality of heaters are in direct thermal contact with the faceplate.

In an additional feature, the first cooling plate is in direct thermal contact with the backplate.

In an additional feature, the first cooling plate comprises a material having a higher thermal conductivity than the metallic material of the backplate.

In an additional feature, the backplate is made of aluminum or an alloy and wherein the first cooling plate is made of copper.

In an additional feature, the first cooling plate and the plurality of heaters lie in a plane parallel to the faceplate.

In an additional feature, the plurality of heaters surrounds the first cooling plate.

In an additional feature, each heater of the plurality of heaters is controlled independently of rest of the plurality of heaters.

In additional features, a portion of each of the plurality of heaters is in direct contact with the faceplate. A remaining portion of the each of the plurality of heaters is encapsulated in an electrically insulating and thermally conducting material.

In additional features, the showerhead further comprises a layer of a thermally resistive material disposed between the plurality of heaters and the backplate. The thermally resistive material has a lower thermal conductivity than the backplate.

In an additional feature, the layer is annular with an inner diameter greater than a diameter of the first cooling plate and with an outer diameter less than or equal to a diameter of the faceplate.

In an additional feature, a diameter of the first cooling plate is greater than or equal to half of a diameter of the faceplate.

In an additional feature, the plurality of heaters is arranged along a circle with a diameter less than or equal to a diameter of the faceplate.

In an additional feature, the first cooling plate comprises a heater.

In an additional feature, the heater is a low power heater compared to the plurality of heaters.

In an additional feature, the heater is in direct thermal contact with at least one of the backplate and the faceplate.

In additional features, the showerhead further comprises a second cooling plate arranged on the backplate. The second cooling plate comprises a cooling channel to circulate a coolant.

In additional features, the showerhead further comprises a layer of a thermally resistive material disposed between the backplate and the second cooling plate. The thermally resistive material has a lower thermal conductivity than the backplate.

In additional features, the showerhead further comprises a plurality of layers of thermally resistive materials disposed between the backplate and the second cooling plate. The thermally resistive material have lower thermal conductivities than the backplate. The thermal conductivities of the layers increase from the backplate to the second cooling plate.

In an additional feature, at least one of the plurality of layers comprises a pattern of features that provide air pockets.

In additional features, the showerhead further comprises a stem comprising a metallic portion and a ceramic portion. The ceramic portion is embedded in the metallic portion and in the backplate.

In additional features, the ceramic portion comprises a plurality of segments extending radially away from the ceramic portion. Distal ends of the segments extending to the faceplate perpendicularly to the segments.

In an additional feature, the distal ends extend to the faceplate via cutouts in the first cooling plate.

In additional features, the stem comprises a gas inlet. The metallic portion, the ceramic portion, and the plurality of segments comprise gas passages in fluid communication with the gas inlet.

In additional features, the faceplate comprises a plurality of through holes. The gas passages are in fluid communication with the through holes.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system comprising a processing chamber;

FIG. 2 shows an example of a showerhead for use in the processing chamber of FIG. 1;

FIG. 3 shows an example of a first cooling plate comprising a heater disposed above a center region of a faceplate of the showerhead of FIG. 2;

FIG. 4 shows an example of the first cooling plate and outer heaters disposed above a peripheral region of the showerhead of FIG. 2;

FIGS. 5 and 6 show an example of a gas distribution manifold of the showerhead of FIG. 2; and

FIG. 7 shows an example of a thermal resistor disposed between a backplate and a second cooling plate disposed above the backplate of the showerhead of FIG. 2.

In the drawings, reference numbers may be reused to identify similar and/or identical elements.

### DETAILED DESCRIPTION

For some processes, pedestals used to support substrates have ceramic top plates, and showerheads used to supply process gases have ceramic faceplates. In these processes, the gap between the top plate of the pedestal and the faceplate of the showerhead is narrow. The processes require heating the showerhead and the pedestal to high temperatures. Further, the pedestal is heated to a higher temperature than the temperature of the showerhead. Due to the narrow gap between the pedestal and the showerhead, heat from the pedestal is coupled to the faceplate of the showerhead.

Some processes use process gases with high thermal conductivity, and these processes have long soak times (i.e., time for which the faceplate is exposed to these gases). In these processes, the faceplate tends to heat more in the center region than in the peripheral region, which causes the center region to darken. Due to the darkening, the center region tends get hotter than the peripheral region, causing a large temperature gradient across the radius of the faceplate, which can damage (e.g., crack) the faceplate.

The present disclosure solves these and other problems by providing a cooling plate above a center region of the faceplate and by providing a plurality of heaters above a peripheral region of the faceplate. The cooling plate and the heaters are arranged between the faceplate and a metal backplate of the showerhead. The cooling plate and the heaters are in thermal contact with the faceplate and backplate. The backplate is cooled using cooling channels disposed above the backplate. The cooling plate conducts heat from the center region of the faceplate. The heat conducted by the cooling plate is transferred to the backplate, which is cooled by the cooling channels.

The heaters disposed above the peripheral region of the faceplate (also called outer heaters) heat the peripheral region of the faceplate. The cooling plate above the center region of the faceplate also comprises a heater. In addition to cooling the center region, the heater in the cooling plate can also heat the center region. By controlling the heat supplied by the cooling plate and the heat supplied by the outer heaters, a uniform temperature gradient can be achieved across the radius of the faceplate.

In some examples, a layer of a thermally resistive material may be disposed between the outer heaters and the backplate. In some examples, one or more layers of a thermally resistive material may also be disposed between the backplate and the cooling channels. These layers may be patterned as explained below in detail.

Additionally, the present disclosure provides gas distribution channels from the stem of the showerhead to the faceplate to supply process gases to the faceplate. The gas distribution channels are designed such that the process gases flowing through the showerhead and process byproducts escaping through the showerhead are decoupled from fluid communication with the cooling plate and the heaters. The decoupling allows optimization of heater material and heating element design without limitation of compatibility with corrosive byproducts of the process chemistry.

Further, the stem, which is connected to the backplate, is subjected to the heat conducted by the backplate. The stem is typically made of a metal coated with an anticorrosive material. To prevent the stem from being damaged by the heat from the backplate, the stem according to the present disclosure comprises an upper metal portion and a lower ceramic portion that is embedded in the upper metal portion. The metal portion is internally lined with an anticorrosive material to prevent corrosion due to the process gases that flow through the stem. The ceramic portion is connected to the backplate. The ceramic portion not only does not corrode due to the process gases but can also withstand the heat from the backplate. Further, the gas distribution channels extend from the ceramic portion to the faceplate and are also made of a ceramic material. The gas distribution channels are routed through cavities in the backplate and the cooling plate. These and other features of the present disclosure are described below in detail.

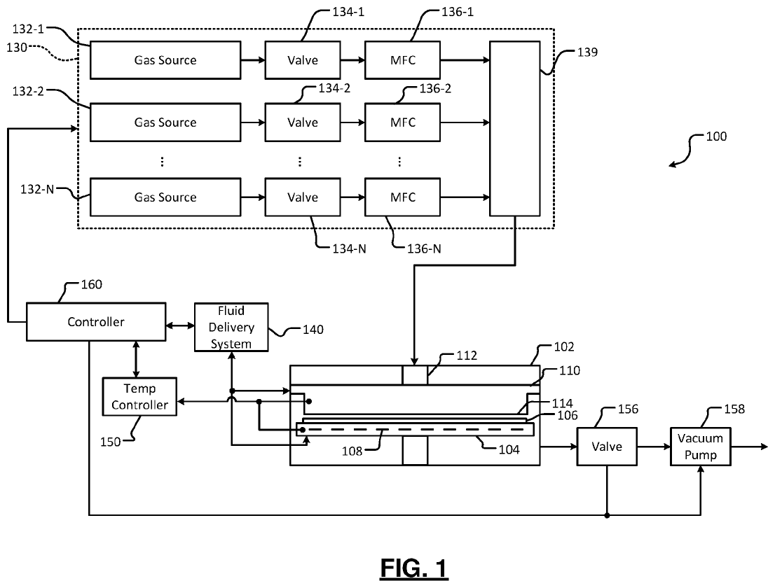

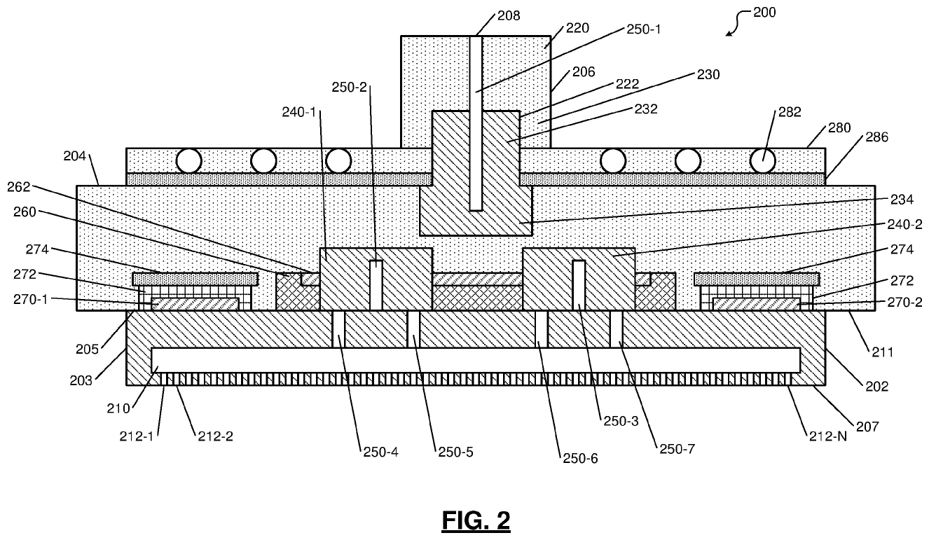

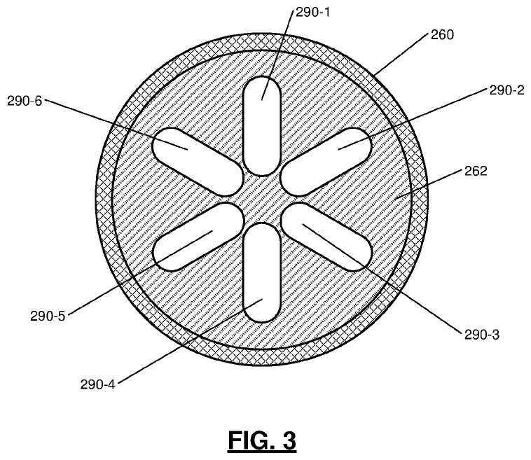

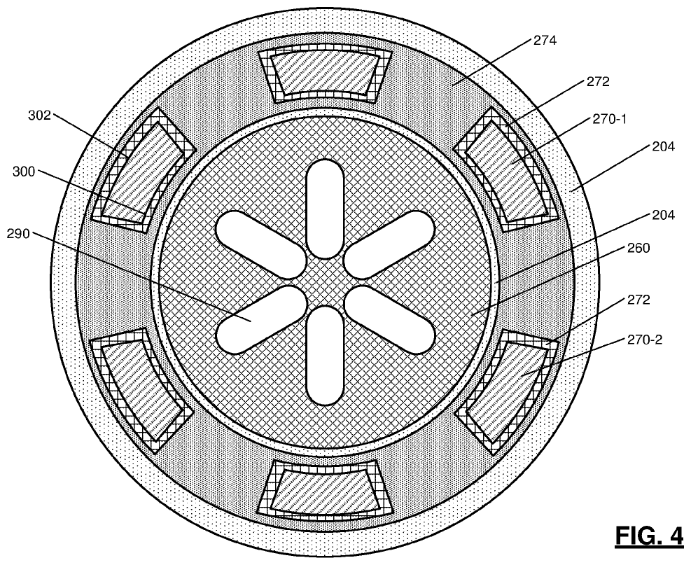

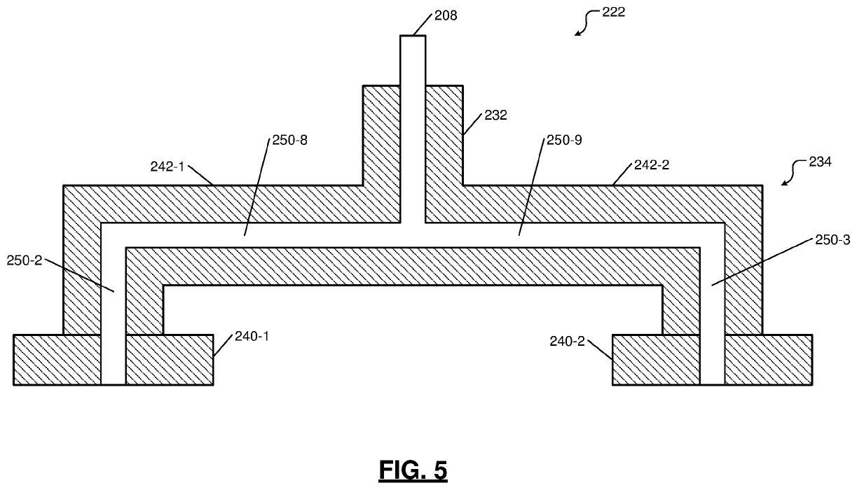

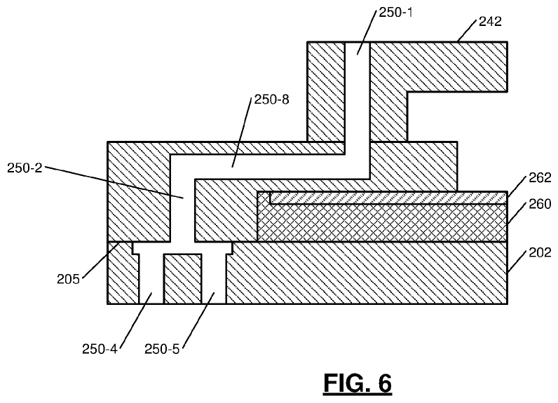

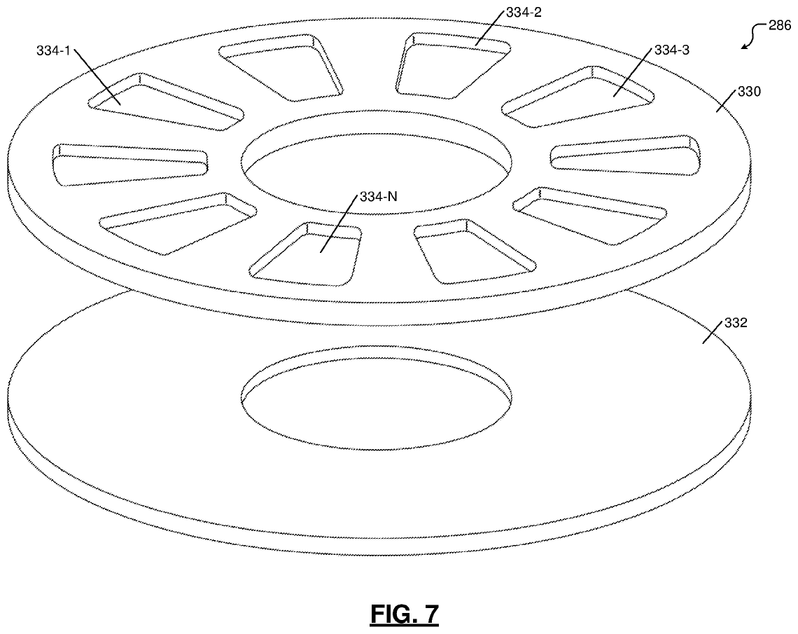

The present disclosure is organized as follows. An example of a processing chamber in which a showerhead according to the present disclosure can be used is shown and described with reference to FIG. 1. A showerhead according to the present disclosure is shown and described with reference to FIG. 2. An example of the cooling plate comprising the heater disposed above the center region of the faceplate of the showerhead is shown and described with reference to FIG. 3. The outer heaters disposed above the peripheral region of the faceplate and the cooling plate are shown and described in further detail with reference to FIG. 4. The ceramic gas distribution manifold embedded in the stem and the backplate of the showerhead is shown and described in further detail with reference to FIGS. 5 and 6. The thermal resistor used between the backplate and the top cooling plate of the showerhead is shown and described in further detail with reference to FIG. 7.

### Example of a Substrate Processing System

FIG. 1 shows an example of a substrate processing system 100 comprising a processing chamber 102 configured to process a substrate using thermal atomic layer deposition (T-ALD). The processing chamber 102 encloses other components of the substrate processing system 100. The processing chamber 102 comprises a substrate support (e.g., a pedestal) 104. During processing, a substrate 106 is arranged on the pedestal 104.

One or more heaters 108 (e.g., a heater array) may be disposed in a ceramic plate arranged on a metallic baseplate of the pedestal 104 to heat the substrate 106 during processing. One or more additional heaters called zone heaters or primary heaters (not shown) may be arranged in the ceramic plate above or below the heaters 108. Additionally, while not shown, a cooling system comprising cooling channels through which a coolant can flow to cool the pedestal 104 may be disposed in the baseplate of the pedestal 104; and one or more temperature sensors may be disposed in the pedestal 104 to sense the temperature of the pedestal 104.

The processing chamber 102 comprises a gas distribution device 110 such as a showerhead to introduce and distribute process gases into the processing chamber 102. The gas distribution device (hereinafter showerhead) 110 comprises a stem 112. One end of the stem 112 is connected to a top surface of the processing chamber 102. A backplate 114 of the showerhead 110 is generally cylindrical and extends radially outwardly from an opposite end of the stem 112 at a location that is spaced from the top surface of the processing chamber 102. A substrate-facing surface of the backplate 114 of the showerhead 110 comprises a faceplate (shown in subsequent figures). The faceplate comprises a plurality of outlets or features (e.g., slots or through holes) through which process gases flow into the processing chamber 102.

The showerhead 110 also comprises a plurality of cooling plates and a plurality of heaters (shown and described with reference to subsequent figures). An upper cooling plate comprises a conduit (see FIG. 2) through which a coolant can be circulated. Additionally, while not shown, one or more temperature sensors may be disposed in the showerhead 110 to sense the temperature of the showerhead 110. The showerhead 110 comprises additional features such as one or more heat resistors, which are shown and described below in detail with reference to subsequent figures.

A gas delivery system 130 comprises one or more gas sources 132-1, 132-2, . . . , and 132-N (collectively, the gas sources 132), where N is an integer greater than zero. The gas sources 132 are connected by valves 134-1, 134-2, . . . , and 134-N (collectively, the valves 134) and mass flow controllers 136-1, 136-2, . . . , and 136-N (collectively, the mass flow controllers 136) to a manifold 139. An output of the manifold 139 is fed to the processing chamber 102. The gas sources 132 may supply process gases, cleaning gases, purge gases, inert gases, etc. to the processing chamber 102.

A fluid delivery system 140 supplies a coolant to the cooling system in the pedestal 104 and to the upper cooling plate in the showerhead 110. A temperature controller 150 may be connected to the heaters 108, the zone heaters, the cooling system, and the temperature sensors in the pedestal 104. The temperature controller 150 may also be connected to the cooling plate, the heaters, and the temperature sensors in the showerhead 110. The temperature controller 150 may control power supplied to the heaters 108, the zone heaters, and coolant flow through the cooling system in the pedestal 104 to control the temperature of the pedestal 104 and the substrate 106. The temperature controller 150 may also control power supplied to the heaters disposed in the showerhead 110 and coolant flow through the conduit disposed in the upper cooling plate of the showerhead 110 to control the temperature of the showerhead 110.

A vacuum pump 158 maintains sub-atmospheric pressure inside the processing chamber 102 during substrate processing. A valve 156 is connected to an exhaust port of the processing chamber 102. The valve 156 and the vacuum pump 158 are used to control pressure in the processing chamber 102 and to evacuate reactants from the processing chamber 102 via the valve 156. A system controller 160 controls the components of the substrate processing system 100.

### Example of Showerhead

FIG. 2 shows a cross-sectional view of a showerhead 200 according to the present disclosure. The showerhead 200 can be used instead of the showerhead 110 in the processing chamber 102 shown in FIG. 1. The showerhead 200 comprises a faceplate 202, a backplate 204, and a stem 206, each of which is cylindrical.

The faceplate 202 is made of a ceramic material. The faceplate 202 comprises a plenum 210 defined by a sidewall 203 of the faceplate 202 and upper and lower surfaces 205, 207 of the faceplate 202. The lower surface 207 of the faceplate 202 comprises a plurality of through holes 212-1, 212-2, . . . , and 212-N (collectively the through holes 212), where N is a positive integer. The through holes 212 extend from the lower surface 207 of the faceplate 202 to the plenum 210. The through holes 212 are in fluid communication with the plenum 210.

The backplate 204 has a larger diameter than the faceplate 202. The backplate 204 is made of a metal such as aluminum or an alloy. The upper surface 205 of the faceplate 202 is attached to a lower surface 211 of the backplate 204. The stem 206 is attached to an upper center region of the backplate 204. The stem 206 comprises an inlet 208 to receive process gases.

The stem 206 comprises a metal portion 220 and a ceramic portion 222 that is embedded into a lower center region 230 of the metal portion 220. The ceramic portion 222 comprise an upper portion 232 and a lower portion 234. The upper portion 232 of the ceramic portion 222 is embedded into the lower center region 230 of the metal portion 220. The lower portion 234 of the ceramic portion 222 is embedded into the upper center region of the backplate 204.

The ceramic portion 222 comprises a plurality of segments (element 242 shown in FIGS. 5 and 6) that extend radially from the lower portion 234 of the ceramic portion 222 through respective slots in the backplate 204. Distal ends of the segments 242 (called ports), of which only two are shown at 240-1, 240-2 (collectively the ports 240), extend perpendicularly to the segments 242 towards the faceplate 202. The ports 240 are disposed in respective slots in the backplate 204. The ports 240 are attached to the upper surface 205 of the faceplate 202 as shown and described below in further detail with reference to FIGS. 5 and 6.

A plurality of gas passages are bored through the metal portion 220 and the ceramic portion 222 of the stem 206, through the segments 242 and the ports 240, and through the faceplate 202. The gas passages are shown at 250-1, 250-2, 250-3, 250-4, 250-5, 250-6, and 250-7 (collectively the gas passages 250). The gas passages 250 are in fluid communication with the inlet 208 in the stem 206 and are in fluid communication with the plenum 210 and the through holes 212 in the faceplate 202. The ceramic portion 222 and the gas passages 250 in the ceramic portion 222 define a gas distribution manifold in the backplate 204. The gas distribution manifold (elements 222, and 250) supplies process gases from the inlet 208 in the stem 206 to faceplate 202.

A first cooling plate 260 is arranged above a center region of the upper surface 205 of the faceplate 202. The first cooling plate 260 is circular and is shown and described below in further detail with reference to FIG. 3. In some examples, the first cooling plate 260 has a diameter that is greater than or equal to one half of the diameter of the faceplate 202.

The first cooling plate 260 is made of a metal (e.g., copper) having a high thermal conductivity. For example, the first cooling plate 260 is made of a material having a higher thermal conductivity than the backplate 204. The first cooling plate 260 is in direct thermal contact with the backplate 204 and is in direct thermal contact with the upper surface 205 of the faceplate 202. The first cooling plate 260 conducts heat from the center region of the faceplate 202 and transfers the conducted heat to the backplate 204.

The first cooling plate 260 also comprises a heater 262, which is shown and described below in further detail with reference to FIG. 3. In some processes, the heater 262 can be used to heat the center region of the faceplate 202. The heater 262 and the first cooling plate 260 extend radially beyond the ports 240 of the ceramic portion 222 of the stem 206 towards an outer diameter (OD) of the faceplate 202.

A plurality of heaters (called outer heaters), of which only two are shown at 270-1 and 270-2 (collectively the outer heaters 270), are arranged above the upper surface 205 of the faceplate 202. The outer heaters 270 are arranged along the periphery (e.g., proximate to an OD) of the faceplate 202. The outer heaters 270 are shown and described below in further detail with reference to FIG. 4. Briefly, the outer heaters 270 are arranged in respective slots in the backplate 204. The outer heaters 270 are encapsulated in an electrically insulating material 272 having a high thermal conductivity (e.g., aluminum nitride). The outer heaters 270 heat the peripheral region of the faceplate 202.

The lower surfaces of the outer heaters 270 may be in direct thermal contact with the upper surface 205 of the faceplate 202. An upper surface of the insulating material 272 may be in direct thermal contact with the backplate 204. In some examples, a first thermal resistor 274 may be disposed between the upper surface of the insulating material 272 and the backplate 204. The first thermal resistor 274 is shown and described below in further detail with reference to FIG. 4. The first thermal resistor 274 can reduce heat transfer from the outer heaters 270 to the backplate 204.

A controller (e.g., the controller 160 shown in FIG. 1) controls the power supplied to the outer heaters 270 and the heater 262 in the first cooling plate 260. The outer heaters 270 are high power heaters compared to the heater 262. The outer heaters 270 can supply more heat than the heater 262. The controller can individually control the outer heaters 270 independently of each other. For example, the controller can not only turn on and off each of the outer heaters 270 but can also control the amount of power supplied to each of the outer heaters 270, which determines the amount of heat generated by each of the outer heaters 270. The heat supplied by the heaters 270, 262 to the faceplate 202 and the heat conducted by the first cooling plate 260 from the faceplate 202 provide temperature uniformity across the radius of the faceplate 202. Further, in some processes, the heaters 270, 262 can be controlled to provide a desired temperature gradient or temperature zones across the radius of the faceplate 202.

A second cooling plate 280 is arranged above the backplate 204. The second cooling plate 280 is annular with an OD less than or equal to the OD of the faceplate 202. The second cooling plate 280 comprises a conduit 282 through which a coolant from a fluid delivery system flows. The second cooling plate 280 can comprise multiple conduits through which the coolant can flow at different flow rates. The second cooling plate 280 cools the backplate 204. The heat conducted by the first cooling plate 260 from the center region of the faceplate 202, which is transferred to the backplate 204, is removed from the backplate 204 by the second cooling plate 280. Some of the heat generated by the outer heaters 270, which is transferred to the backplate 204, is also removed from the backplate 204 by the second cooling plate 280.

The coolant flowing through the conduit 282 can become hot as heat flows from the faceplate 202 to the second cooling plate 280 and can lose the ability to provide cooling (i.e., cooling capacity). For example, if water is used as the coolant (although other coolants can be used), the water can boil at 100 degrees Celsius and lose cooling capacity. Since the temperature of the showerhead 200 can reach several hundred degrees Celsius, the temperature of the coolant needs to be kept well below a boiling point of the coolant (e.g., well below 100 degrees Celsius if water is used as coolant). This is accomplished by disposing a second thermal resistor (also called a heat choke) 286 between the backplate 204 and the second cooling plate 280.

The heat choke 286 is shown and described below in further detail with reference to FIG. 7. Briefly, the heat choke 286 can comprise a plurality of layers of materials having thermal conductivities different than the metal or alloy used to form the backplate 204. At least one of the layers can be patterned as explained below with reference to FIG. 7. Due to the layers of different thermal conductivities, the heat choke 286 gradually impedes heat flow from the backplate 204 to the second cooling plate 280, which prevents the coolant from overheating and boiling.

### Examples of Cooling Plate and Heater Used Above Faceplate

FIG. 3 shows a top view of the first cooling plate 260 with the heater 262. The first cooling plate 260 is circular. The heater 262 comprises a circular plate having a smaller diameter than the first cooling plate 260. The heater 262 is arranged in an upper portion of the first cooling plate 260. Upper surfaces of the first cooling plate 260 and the heater 262 are coplanar. The heater 262 is in direct thermal contact with the backplate 204 and with the first cooling plate 260. The heater 262 is electrically insulated from the first cooling plate 260 and the backplate 202.

Further, as shown in FIG. 2, a thickness or height of the heater 262 is less than that of the first cooling plate 260. The heater 262 is shown to be closer to the backplate 204 than to the faceplate 202. However, the heater 262 can be arranged closer to the faceplate 202 than to the backplate 204. Alternatively, the heater 262 can be disposed in a center portion of the first cooling plate 260 such that the heater 262 is equidistant from both the faceplate 202 and the backplate 204.

A plurality of cutouts 290-1, 290-2, . . . , 290-6 (collectively the cutouts 290) are provided in the first cooling plate 260 with the heater 262. The segments 242 of the ceramic portion 222 (shown in FIG. 5) pass through the cutouts 290.

### Examples of Outer Heaters Used Above Faceplate

FIG. 4 shows a bottom view of the first cooling plate 260 and the outer heaters 270. The bottom view shows the outer heaters 270 and the first thermal resistor 274 in further detail. Elements identified using the same reference numerals as those used in FIGS. 2 and 3 are already described with reference to FIGS. 2 and 3 and are therefore not described again for brevity.

The outer heaters 270 surround the first cooling plate 260. The outer heaters 270 and the first cooling plate 260 lie in a plane parallel to the faceplate 202. The outer heaters 270 are generally pie shaped although the outer heaters 270 can be of any other shape. Further, the outer heaters 270 can be radially equidistant (i.e., may lie along a circle) as shown. Alternatively, the outer heaters 270 may be arranged in different patterns. For example, one set of the outer heaters 270 may lie on a first circle having a first radius while another set of the outer heaters 270 may lie on a second circle having a second radius that is different than the first radius.

In the example shown, the outer heaters 270 comprise an inner curved portion 300 and an outer curved portion 302. The inner curved portions 300 of all of the outer heaters 270 have the same radius. The inner curved portions 300 of all of the outer heaters 270 lie on a first circle having a first radius R1. The outer curved portions 302 of all of the outer heaters 270 have the same radius. The outer curved portions 302 of all of the outer heaters 270 lie on a second circle having a second radius R2>R1. The first and second circles are concentric. Centers of the first and second circles align with the centers of the faceplate 202, the backplate 204, the stem 206, the first cooling plate 260, and the heater 262.

The first thermal resistor 274 is annular. An inner diameter (ID) of the first thermal resistor 274 is greater than the OD of the first cooling plate 260. An outer diameter (OD) of the first thermal resistor 274 is less than or equal to the OD of the faceplate 202 (as shown in FIG. 2). The ID of the first thermal resistor 274 is less than the diameter of the first circle with radius R1 on which the inner curved portions 300 of all of the heaters 270 lie. The OD of the first thermal resistor 274 is greater than the diameter of the second circle with radius R2 on which the outer curved portions 302 of all of the heaters 270 lie.

The first thermal resistor 274 is made of a material having a different (lower) thermal conductivity than the metal or alloy used to form the backplate 204 and the insulating material 272 used to encapsulate the outer heaters 270. Therefore, the first thermal resistor 274 impedes heat flow from the outer heaters 270 to the backplate 204.

### Example of Gas Distribution Manifold

FIGS. 5 and 6 show the ceramic portion 222 of the stem 206 in further detail. FIG. 5 shows a cross-sectional view of the ceramic portion 222 from a different angle than that shown in FIG. 2 to show the segments of the ceramic portion 222. FIG. 6 shows a cross-sectional view of the ceramic portion 222 along with neighboring elements of the showerhead 200 in further detail. In FIGS. 5 and 6, elements identified using the same reference numerals as those used in FIGS. 1-4 are already described with reference to FIGS. 1-4 and are therefore not described again for brevity.

FIG. 5 shows the segments 242-1, 242-2 (collectively the segments 242) that extend radially outwards from a base of the ceramic portion 222 towards the OD of the backplate 204. While only two segments 242 are shown, the showerhead 200 can comprise multiple segments 242. For example, the showerhead 200 can comprise six segments 242 and six ports 240. In general, the showerhead 200 can comprise a plurality of the segments 242 and the respective ports 240. Distal ends of the segments 242 extend perpendicularly to the segments 242 and parallel to a vertical axis of the showerhead 200 to form the ports 240. The ports 240 are attached to the upper surface 205 of the faceplate 202.

The segments 242 comprise additional gas passages 250-8 and 250-9 that are not visible in FIG. 2. The gas passages 250-8 and 250-9 are in fluid communication with the rest of the gas passages 250 and are integral parts of the gas distribution manifold described above with reference to FIG. 2.

FIG. 6 shows the segment 242 and the port 240 in further detail. A portion of the segment 242 and the port 240 overlaps a radially outer portion of the first cooling plate 260 and a radially outer portion of the heater 262. The port 240 is attached to the upper surface 205 of the faceplate 202 such that the gas passages 250 in the port 240 align with and are in fluid communication with the respective gas passages 250 in the faceplate 202. The partial overlap between the first cooling plate 260 and the portions of the segment 242 and the port 240 prevents overheating of the gas distribution manifold (i.e., elements 222, 242, and 240).

### Example of Heat Choke Used Between Backplate and Cooling Plate

FIG. 7 shows an example of the heat choke 286 that is disposed between the second cooling plate 280 and the backplate 204 as shown in FIG. 2. For example, the heat choke 286 comprises a first plate 330 and a second plate 332. The outer diameters of the first and second plates 330, 332 are less than or equal to the OD of the backplate 204. The first and second plates 330, 332 are made of materials having different thermal conductivities, each of which is less than the thermal conductivity of the material of which the backplate 204 is made.

For example, if the backplate 204 is made of aluminum, the first plate 330 can be made of stainless steel, and the second plate 332 can be made of a non-metal (e.g., a semiconductor material). For example, the thermal conductivity of the first plate 330 is less than that of the backplate 204 and greater than that of the second plate 332. Accordingly, the first and second plates 330, 332 form a thermal resistor (i.e., the heat choke 286) that gradually impedes heat flow (i.e., makes the heat flow gradual) from the backplate 204 to the second cooling plate 280 to prevent overheating of the coolant in the conduit 282. Specifically, the thermal resistor (i.e., the heat choke 286) prevents the coolant that flows through the second cooling plate 280 from reaching its boiling point.

The first plate 330 additionally comprises the recessed portions 334, which provide air pockets that further increase the thermal resistance of the thermal resistor (i.e., the heat choke 286). Specifically, the first plate 330 comprises a plurality of recessed portions 334-1, 334-2, 334-3, . . . , and 334-N, where N is an integer greater than 1 (collectively, the recessed portions 334). The recessed portions 334 can be arranged on at least one of the top and bottom surfaces of the first plate 330. The size, shape, and quantity of the recessed portions 334 on the top surface of the first plate 330 can be such that about 65% of the surface area of the top surface of the first plate 330 is in contact with the bottom surface of the second cooling plate 280.

Similarly, the size, shape, and quantity of the recessed portions 334 on the bottom surface of the first plate 330 can be such that about 65% of the surface area of the bottom surface of the first plate 330 is in contact with the top surface of the second plate 332. Other percentages may be used for contact areas of the top and bottom surfaces of the first plate 330. For example, the contact areas of the top and bottom surfaces of the first plate 330 may vary between 50-80%. Further, the contact areas of the top and bottom surfaces of the first plate 330 may be different (i.e., unequal).

More specifically, the first and second plates 330, 332 are made of materials having relatively low thermal conductivities. The first plate 330 may have a higher thermal conductivity than the second plate 332. The first and second plates 330, 332 provide thermal barriers for heat flowing from the backplate 204 to the second cooling plate 280. The second plate 332 provides a thermal barrier for heat flowing from the backplate 204 to the first plate 330, and the first plate 330 provides a thermal barrier for heat flowing from the second plate 332 to the second cooling plate 280. The first and second plates 330, 332 function as heat chokes or thermal resistors that are in series with each other. Accordingly, the second plate 332 and the first plate 330 present a gradually increasing thermal barrier or thermal resistance to the heat flowing from the backplate 204 to the second cooling plate 280.

The recessed portions 334 comprise air pockets and are spaced throughout the first plate 330 on at least one of the top and bottom surfaces to further increase the thermal barrier. The stack of the first and second plates 330, 332 forms the thermal resistor (i.e., the heat choke 286) that prevents the second cooling plate 280 from conducting relatively large amount of heat away from the backplate 204, which can force the outer heaters 270 to operate at a relatively higher capacity.

The thermal resistor (i.e., the heat choke 286) also prevents the coolant (e.g., water) in the conduit 282 from approaching its boiling point due to the heat flow. Accordingly, the second cooling plate 280, the outer heaters 270, the heat choke 286, the first cooling plate 260, and the heater 262 provide a balance between the heating and cooling of the showerhead 200 to minimize the temperature gradient across the faceplate 202.

The first plate 330 may be manufactured as a monolithic plate. Alternatively, the first plate 330 may comprise three layers: two layers (top and bottom layers) comprising the recessed portions 334 (in the form of recesses or slots that are cut through the layers), and a third layer that is flat (i.e., without the recessed portions 334) and that is sandwiched between the two layers. The three layers may be bonded to each other (e.g., brazed or diffusion bonded).

The recessed portions 334 can be arranged on at least one of the top and bottom surfaces of the first plate 330 in many ways. The recessed portions 334 on the top surface of the first plate 330 may be aligned with the recessed portions 334 on the bottom surface of the first plate 330. Alternatively, the recessed portions 334 on the top surface of the first plate 330 may be offset relative to the recessed portions 334 on the bottom surface of the first plate 330. For example, the recessed portions 334 on the top surface of the first plate 330 may overlap at least one of the recessed portions 334 on the bottom surface of the first plate 330. Alternatively, none of the recessed portions 334 on the top surface of the first plate 330 may overlap the recessed portions 334 on the bottom surface of the first plate 330.

The recessed portions 334 on the top and bottom surfaces of the first plate 330 can have any size, shape, and quantity so long as the contact areas of the top and bottom surfaces of the first plate 330 are as described above. For example, the recessed portions 334 on the top and bottom surfaces of the first plate 330 may be of the same size and shape. Alternatively, the recessed portions 334 on the top surface of the first plate 330 may be of a different size and/or shape than the recessed portions 334 on the bottom surface of the first plate 330. The recessed portions 334 can be arranged on the top and bottom surfaces of the first plate 330 symmetrically or asymmetrically.

The number of the recessed portions 334 can be different (e.g., fewer or more) than that shown. The top and bottom surfaces of the first plate 330 may have the same number of the recessed portions 334. Alternatively, the top surface of the first plate 330 may comprise different number of the recessed portions 334 than the bottom surface of the first plate 330. The depth of the recessed portions 334 can be the same or can be different. The recessed portions 334 on the top and bottom surfaces of the first plate 330 can have the same depth. Alternatively, the recessed portions 334 on the top surface of the first plate 330 can have a first depth, and the recessed portions 334 on the bottom surface of the first plate 330 can have a second depth. The depths of the recessed portions 334 on the top surface of the first plate 330 can vary in a first pattern, and the depths of the recessed portions 334 on the bottom surface of the first plate 330 can vary in a second pattern. Any combination of the above variations may be used.

The ODs of the first and second plates 330, 332 are less than or equal to the OD of the second cooling plate 280 The thicknesses of the first and second plates 330, 332 can be varied depending on process requirements. The first plate 330 may be thicker than the second plate 332. In some applications, the second plate 332 may also comprise recessed portions on at least one of top and bottom surfaces and may comprise any of the variations described above with reference to the first plate 330.

Further, there may be additional permutations and combinations possible between the recessed portions of the first and second plates 330, 332. In some applications, the second plate 332 can be made of a thermoplastic material (e.g., polyimide), can comprise all of the structural features of the first plate 330 described above, and can be used independently (i.e., by itself instead of being used together with the first plate 330). Alternatively, in some applications, the second plate 332 may be omitted, and the first plate 330 can be made of the thermoplastic material (e.g., polyimide).

Further, while not shown, a third plate having a relatively low thermal conductivity may be used in addition to the first and second plates 330, 332. The third plate may be similar to any of the first and second plates 330, 332 except that the thermal conductivity of the third plate may be different than the first and second plates 330, 332. The third plate may be arranged above, below, or between the first and second plates 330, 332. The thermal conductivity of the third plate may be selected based on the location of the third plate. For example, the third plate arranged below the second plate 332 may have a lower thermal conductivity than the second plate 332. The third plate arranged above the first plate 330 may have a higher thermal conductivity than the first plate 330. The third plate arranged between the first and second plates 330, 332 may have a thermal conductivity less than the first plate 330 and greater than the second plate 332.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate.

The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A showerhead for a substrate processing system comprising:
a backplate made of a metallic material;
a faceplate made of a ceramic material;
a first cooling plate arranged between the backplate and a center region of the faceplate; and
a plurality of heaters arranged between the backplate and a peripheral region of the faceplate.

2. The showerhead of claim 1 wherein the first cooling plate and the plurality of heaters are in direct thermal contact with the faceplate.

3. The showerhead of claim 1 wherein the first cooling plate is in direct thermal contact with the backplate.

4. The showerhead of claim 1 wherein the first cooling plate comprises a material having a higher thermal conductivity than the metallic material of the backplate.

5. The showerhead of claim 1 wherein the backplate is made of aluminum or an alloy and wherein the first cooling plate is made of copper.

6. The showerhead of claim 1 wherein the first cooling plate and the plurality of heaters lie in a plane parallel to the faceplate.

7. The showerhead of claim 1 wherein the plurality of heaters surrounds the first cooling plate.

8. The showerhead of claim 1 wherein each heater of the plurality of heaters is controlled independently of rest of the plurality of heaters.

9. The showerhead of claim 1 wherein a portion of each of the plurality of heaters is in direct contact with the faceplate and wherein a remaining portion of the each of the plurality of heaters is encapsulated in an electrically insulating and thermally conducting material.

10. The showerhead of claim 1 further comprising a layer of a thermally resistive material disposed between the plurality of heaters and the backplate wherein the thermally resistive material has a lower thermal conductivity than the backplate.

11. The showerhead of claim 10 wherein the layer is annular with an inner diameter greater than a diameter of the first cooling plate and with an outer diameter less than or equal to a diameter of the faceplate.

12. The showerhead of claim 1 wherein a diameter of the first cooling plate is greater than or equal to half of a diameter of the faceplate.

13. The showerhead of claim 1 wherein the plurality of heaters is arranged along a circle with a diameter less than or equal to a diameter of the faceplate.

14. The showerhead of claim 1 wherein the first cooling plate comprises a heater.

15. The showerhead of claim 14 wherein the heater is a low power heater compared to the plurality of heaters.

16. The showerhead of claim 14 wherein the heater is in direct thermal contact with at least one of the backplate and the faceplate.

17. The showerhead of claim 1 further comprising a second cooling plate arranged on the backplate wherein the second cooling plate comprises a cooling channel to circulate a coolant.

18. The showerhead of claim 17 further comprising a layer of a thermally resistive material disposed between the backplate and the second cooling plate wherein the thermally resistive material has a lower thermal conductivity than the backplate.

19. The showerhead of claim 17 further comprising a plurality of layers of thermally resistive materials disposed between the backplate and the second cooling plate wherein the thermally resistive material have lower thermal conductivities than the backplate and wherein the thermal conductivities of the layers increase from the backplate to the second cooling plate.

20. The showerhead of claim 19 wherein at least one of the plurality of layers comprises a pattern of features that provide air pockets.

21. The showerhead of claim 1 further comprising a stem comprising a metallic portion and a ceramic portion wherein the ceramic portion is embedded in the metallic portion and in the backplate.

22. The showerhead of claim 21 wherein the ceramic portion comprises a plurality of segments extending radially away from the ceramic portion and wherein distal ends of the segments extending to the faceplate perpendicularly to the segments.

23. The showerhead of claim 22 wherein the distal ends extend to the faceplate via cutouts in the first cooling plate.

24. The showerhead of claim 22 wherein the stem comprises a gas inlet and wherein the metallic portion, the ceramic portion, and the plurality of segments comprise gas passages in fluid communication with the gas inlet.

25. The showerhead of claim 24 wherein the faceplate comprises a plurality of through holes and wherein the gas passages are in fluid communication with the through holes.
